(19) United States
(12) Patent Application Publication
(10) Pub. No.: US 2022/0380884 A1
(43) Pub. Date: Dec. 1, 2022

(54) NICKEL ALLOY SPUTTERING TARGET

(71) Applicant: MITSUBISHI MATERIALS CORPORATION, Tokyo (JP)

(72) Inventor: Shinji Kato, Sanda-shi (JP)

(73) Assignee: MITSUBISHI MATERIALS CORPORATION, Tokyo (JP)

(21) Appl. No.: 17/619,354

(22) PCT Filed: Jun. 18, 2020
(86) PCT No.: PCT/JP2020/024031

§ 371 Date: Dec. 15, 2021

(30) Foreign Application Priority Data
Jul. 12, 2019 (JP) 2019-130518

(51) Int. Cl. C23C 14/34; C22C 19/03; C22C 19/00

(52) U.S. Cl. CPC C23C 14/3407; C22C 19/03; C22C 19/007

(57) ABSTRACT

A nickel alloy sputtering target comprises: a nickel alloy containing an element capable of decreasing the Curie temperature of nickel, wherein an area ratio of a Ni phase having a Ni content of 99.0 mass % or more is 13% or less and an average crystal grain diameter is 100 gm or less. It is preferred that an area ratio of a high-purity Ni phase having a Ni content of 99.5 mass % or more be 5% or less.

### TECHNICAL FIELD

The present invention relates to a nickel alloy sputtering target used at the time of forming a nickel alloy thin film.

Priority is claimed on Japanese Patent Application No. 2019-130518, filed Jul. 12, 2019, the content of which is incorporated herein by reference.

### BACKGROUND ART

When the nickel alloy thin film described above is formed, for example, as described in Patent Literature 1, a sputtering method in which a sputtering target composed of a nickel alloy having a prescribed composition is utilized is applied. Since nickel is ferromagnetic, when a film is formed using a magnetron sputtering device, a sputtering target composed of a nickel alloy may be adsorbed on the device due to a magnetic force, whereby it is not possible to stably form a film.

Also, when the sputtering progresses, a narrow erosion portion is formed, which causes a problem that the utilization efficiency of a sputtering target is lowered.

Patent Literature 1 proposes a technique for weakening the magnetism of a nickel alloy by dissolving silicon in nickel as a solid solution. When Si atoms are dissolved in nickel as a solid solution, a spin direction of Ni atoms changes, which makes it possible to weaken the magnetism.

### CITATION LIST

### Patent Literature 1

Japanese Patent No. 3532063

### SUMMARY OF INVENTION

Technical Problem

In Patent Literature 1, for the purpose of thoroughly dissolving Si atoms in nickel as a solid solution, a sputtering target is produced by performing homogenization heat treatment by heating an ingot obtained by performing melt-casting under high temperature conditions of 1000 to 1200° C. and then subjecting the ingot to hot rolling or hot forging.

Since the heat treatment is performed under high temperature conditions as described above in Patent Literature 1, the crystal grains are coarsened. When the crystal grains are coarsened, there is a concern concerning Si which is not dissolved as a solid solution becoming concentrated at the crystal grain boundaries, abnormal electric discharge easily occurring at the time of sputtering film formation, and sputtering film formation which cannot be performed stably.

Also, in a sputtering target whose crystal grains are coarsened, there is a concern concerning a sputtering rate on a sputtered surface varying and a film thickness of the formed nickel alloy thin film becoming non-uniform.

The present invention was made in view of the above-described circumstances, and an object of the present invention is to provide a nickel alloy sputtering target in which magnetism is weakened, a magnetic flux leakage increases, coarsening of crystal grains is minimized, a nickel alloy thin film with a uniform film thickness can be stably formed, a wide erosion portion is formed when sputtering progresses, and utilization efficiency can be improved.

### Solution to Problem

In order to achieve this object, a nickel alloy sputtering target according to an aspect of the present invention includes: a nickel alloy containing an element capable of decreasing the Curie temperature of nickel, wherein an area ratio of a Ni phase having a Ni content of 99.0 mass % or more is 13% or less and an average crystal grain diameter is 100 μm or less.

According to the nickel alloy sputtering target of the present invention, since an element capable of decreasing the Curie temperature of nickel is contained and the area ratio of the Ni phase having a Ni content of 99.0 mass % or more is 13% or less, when the element capable of decreasing the Curie temperature is sufficiently dissolved in nickel as a solid solution, the magnetism is weakened, the magnetic flux leakage increases, and the when a magnetron sputtering device is utilized, it is possible to prevent the sputtering target from being absorbed on the device and it is possible to stably perform sputtering film formation. Furthermore, when sputtering progresses, a relatively wide erosion portion is formed and it is possible to improve the efficiency of utilizing the sputtering target.

Also, since the average crystal grain diameter is 100 μm or less, it is possible to minimize the concentration of the element capable of decreasing the Curie temperature of nickel at the crystal grain boundaries. Thus, it is possible to minimize the occurrence of abnormal electrical discharge and it is possible to stably perform sputtering film formation. Furthermore, it is possible to minimize the sputtering rate variation on the sputtered surface and it is possible to form a nickel alloy film with a uniform film thickness. In addition, when the average crystal grain diameter is 100 μm or less and the concentration of the additive element is minimized at the grain boundaries, it is possible to sufficiently dissolve the additive element in nickel as a solid solution and it is possible to more stably weaken the magnetism.

In the nickel alloy sputtering target of the present invention, it is more preferable that the area ratio of the high-purity Ni phase having a Ni content of 99.5 mass % or more be 5% or less. In this case, even when the element capable of decreasing the Curie temperature is more thoroughly dissolved in nickel as a solid solution, the magnetism is weakened, and the magnetic flux leakage increases, and when the magnetron sputtering device is utilized, it is possible to prevent the sputtering target from adsorbing to the device and it is possible to more stably perform sputtering film formation. Furthermore, when sputtering progresses, the erosion portion is formed relatively wide and it is possible to further improve the utilization efficiency of the sputtering target. It is possible to measure the area ratio of the Ni phase and the high-purity Ni phase using the method which will be described later. It is also possible to measure the average crystal grain diameter using the method which will be described later.

Also, in the nickel alloy sputtering target of the present invention, it is preferable that one or both of Si and Al be contained as the element capable of decreasing the Curie temperature of nickel and the total content of Si and Al be within a range of 3 mass % or more and 10 mass % or less. In this case, when Si atoms and Al atoms are dissolved as a solid solution, even when the magnetism is weakened, the magnetic flux leakage increases, and the magnetron sputtering device is utilized, it is possible to prevent the sputtering target from adsorbing to the device and it is possible to stably perform sputtering film formation. Furthermore, even when sputtering progresses, the erosion portion is formed relatively wide and it is possible to improve the utilization efficiency of the sputtering target.

### ADVANTAGEOUS EFFECTS OF INVENTION

According to the nickel alloy sputtering target of the present invention, it is possible to stably form a nickel alloy thin film with a uniform film thickness by weakening magnetism, increasing a magnetic flux leakage, and minimizing coarsening of crystal grains. Furthermore, since a wide erosion portion is formed when sputtering progresses, it is possible to improve utilization efficiency.

### BRIEF DESCRIPTION OF DRAWINGS

FIG. 1 is a flowchart for describing an example of a method for producing a nickel alloy sputtering target which is an embodiment of the present invention.

FIG. 2 is a diagram for explaining sampling positions of measurement samples (samples) in rectangular flat plate-shaped nickel alloy sputtering targets in examples of the present invention and comparative examples.

FIG. 3A is an observation photograph of a microstructure of a nickel alloy sputtering target in Example 2 of the present invention.

FIG. 3B is an observation photograph of a microstructure of a sputtering target in Comparative Example 4.

FIG. 4 is a diagram for explaining measurement positions of a film thickness in a formed nickel alloy film in examples of the present invention and comparative examples.

### DESCRIPTION OF EMBODIMENTS

A nickel alloy sputtering target according to an embodiment of the present invention will be described below. A shape of the nickel alloy sputtering target in the embodiment is not limited. In addition, the nickel alloy sputtering target in the embodiment may be a rectangular flat plate-shaped sputtering target having a rectangular sputtered surface or a disc-shaped sputtering target having a circular sputtered surface. Alternatively, the nickel alloy sputtering target in the embodiment may be a cylindrical sputtering target in which a sputtered surface is a cylindrical surface.

The nickel alloy sputtering target in the embodiment is composed of a nickel alloy containing an element capable of decreasing the Curie temperature of nickel. Examples of the element capable of decreasing the Curie temperature of nickel include Si, Al, Ti, Cr, V, and the like.

It is preferable that the nickel alloy sputtering target which is the embodiment contain either or both of Si and Al as an element capable of decreasing the Curie temperature of nickel. Although the total content of Si and Al is not limited, the total content is preferably within a range of 3 mass % or more and 10 mass % or less.

In the nickel alloy sputtering target which is the embodiment, the above-described element such as Si and Al capable of decreasing the Curie temperature of nickel is made to form a solid solution by being dissolved in a nickel matrix. Thus, an area ratio of an Ni phase having a Ni content of 99.0 mass % or more is set to 13% or less.

Also, in the nickel alloy sputtering target which is the embodiment, it is preferable that an area ratio of a high-purity Ni phase having a Ni content of 99.5 mass % or more be 5% or less.

Also, the nickel alloy sputtering target which is the embodiment has an average crystal grain diameter of 100 μm or less.

The reasons for defining the element capable of decreasing the Curie temperature of nickel, the total content of Si and Al, the area ratio of the Ni phase, the area ratio of the high-purity Ni phase, and the average crystal grain diameter as described above in the nickel alloy sputtering target which is the embodiment will be described below.

(Element Capable of Decreasing Curie Temperature of Nickel)

Since nickel is a ferromagnet, magnetization is easily performed therewith. When the element (for example, Si atoms or Al atoms) capable of decreasing the Curie temperature of nickel is dissolved as a solid solution, a spin direction of the Ni atoms changes, which makes it possible to weaken the magnetism.

For this reason, in the nickel alloy sputtering target which is the embodiment, the element capable of decreasing the Curie temperature of nickel is dissolved in nickel to form a solid solution and the magnetism is thus sufficiently weakened.

(Total Content of Si and Al)

As described above, Si and Al are elements capable of decreasing the Curie temperature of nickel. When the total content of Si and Al is set to 3 mass % or more, it is possible to sufficiently weaken the magnetism of the nickel alloy sputtering target. On the other hand, when the total content of Si and Al is set to 10 mass % or less, it is possible to sufficiently minimize a concentration of Si and Al at the crystal grain boundaries and it is possible to minimize the occurrence of abnormal electric discharge at the time of sputtering. Thus, in the nickel alloy sputtering target which is the embodiment, it is preferable to define the total content of Si and Al as being within a range of 3 mass % or more and 10 mass % or less.

A lower limit of the total content of Si and Al is more preferably 5 mass % or more and still more preferably 6 mass % or more. Furthermore, an upper limit of the total content of Si and Al is more preferably 9 mass % or less.

When Ti, Cr, and V are also contained as elements capable of decreasing the Curie temperature of nickel, the total content of Ti, Cr, and V may be 5 mass % or more and 15 mass % or less or 7 mass % or more and 10 mass % or less.

(Area Ratio of Ni Phase)

As described above, when the element (Si and Al in the embodiment) capable of decreasing the Curie temperature of nickel is dissolved in the nickel matrix as a solid solution, the magnetism of nickel is weakened.

If the area ratio of the Ni phase having a Ni content of 99.0 mass % or more increases, there is a concern concerning the area ratio of the phase in which the element capable of decreasing the Curie temperature of nickel is dissolved as a solid solution decreasing and the magnetism of the nickel alloy sputtering target not being able to be sufficiently weakened.

Thus, in the nickel alloy sputtering target which is the embodiment, the area ratio of the Ni phase having a Ni content of 99.0 mass % or more is limited to 13% or less. The area ratio of the Ni phase having a Ni content of 99.0 mass % or more is more preferably 9% or less, and still more preferably 7% or less. Although a lower limit of the area ratio of the Ni phase having a Ni content of 99.0 mass % or more is not limited, for example, the lower limit may be 1.0% or more.

(Area Ratio of High-Purity Ni Phase)

In the high-purity Ni phase having a Ni content of 99.5 mass % or more, the element capable of decreasing the Curie temperature of nickel is not sufficiently dissolved as a solid solution and the magnetism of nickel is not weakened.

In the nickel alloy sputtering target which is the embodiment, in order to reliably weaken the magnetism, the area ratio of the high-purity Ni phase having a Ni content of 99.5 mass % or more is limited to 5% or less.

The area ratio of the high-purity Ni phase having a Ni content of 99.5 mass % or more is more preferably 4% or less, and still more preferably 2% or less. Although a lower limit of the area ratio of the high-purity Ni phase is not limited, for example, the lower limit may be 0.1% or more.

The area ratio of the Ni phase can be obtained as follows. Two virtual lines which intersect through a center point of the sputtered surface are drawn on the sputtered surface (when the sputtered surface is not a flat surface having a cylinder shape or the like, a state of being expanded on the flat surface is considered) of the nickel alloy sputtering target. These virtual lines are diagonal lines when the sputtered surface is rectangular and are two line segments which intersect at a center point on the sputtered surface when the sputtered surface is circular or elliptical. Samples are taken from five points such as an intersection (1) in which the two virtual lines intersect and end portions (2), (3), (4), and (5) on the virtual lines. The end portions are set to a range within 10% of the total length of the virtual line from both ends of the virtual line. After each of the taken samples is embedded in an epoxy resin and a surface (a surface corresponding to the sputtered surface) is subjected to polishing processing, Ni, Si, and Al are mapped in a 60-fold field of view (1400 μm×2000 μm) using FE-EPMA (for example, DCA-8500F manufactured by JEOL Ltd.). For each mapping result, semi-quantitative calculation is performed on each pixel assuming that only Ni, Si, and Al are present using a quantitative map function of FE-EPMA and a quantitative map showing the content (mass %) of each pixel of Ni, Si, and Al is created. Based on the created quantitative map, the area ratio of the Ni phase having a Ni content of 99.0 mass % or more in the field of view and the area ratio of the high-purity Ni phase having a Ni content of 99.5 mass % or more in the field of view are calculated. The area ratio is calculated by counting the number of pixels having a Ni content of 99.0 mass % or more or 99.5 mass % or more and dividing the calculated result by the total number of pixels in the field of view. Furthermore, an average value of the values in (1) to (5) is calculated and used as an area ratio of a Ni phase.

(Average Crystal Grain Diameter)

In the nickel alloy sputtering target, when a crystal grain diameter is large, elements such as Si and Al which have not been dissolved as a solid solution are concentrated at crystal grain boundaries so that the elements are easily partially magnetized. Thus, abnormal electric discharge easily occurs at the time of sputtering film formation. Furthermore, if the crystal grain diameter is large, there is a concern concerning a sputtering rate on a sputtered surface varying and a film thickness becoming non-uniform.

For this reason, in the nickel alloy sputtering target which is the embodiment, an average crystal grain diameter is 100 μm or less. The average crystal grain diameter of the nickel alloy sputtering target is preferably 90 μm or less, and more preferably 80 μm or less.

The average crystal grain diameter can be obtained as follows. As in the case of obtaining the area ratio of the Ni phase, two virtual lines are determined on the sputtered surface and samples are taken from five points such as the intersection (1) of these virtual lines and end portions (2), (3), (4), and (5) on the virtual lines. After the surface of each of the taken samples (the surface corresponding to the sputtered surface) is subjected to polishing processing with diamond abrasive grains, the polished surface is etched with an etching solution (for example, is immersed in a 30 mass % nitric acid aqueous solution at room temperature for 2 minutes). Subsequently, the polished surface is microscopically observed using an optical microscope, and the crystal grain diameter is measured through the cutting method defined in JIS H 0501:1986. The crystal grain diameters are measured in the five samples (1) to (5) described above and the average crystal grain diameter is calculated by averaging them.

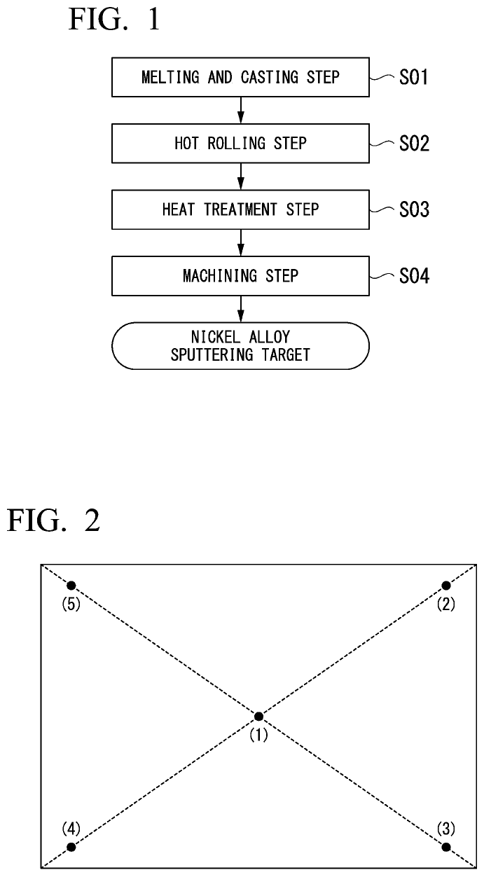

The method for producing a nickel alloy sputtering target which is the embodiment will be described below with reference to the flowchart in FIG. 1.

(Melting and Casting Step S01)

First, as raw materials, a Ni plate and grains of additive elements such as Si and Al are prepared. The purity of the Ni raw material is preferably 99.9 mass % or more. Furthermore, the purities of the Si raw material and the Al raw material are preferably 99.9 mass % or more.

Subsequently, the Ni raw material, the Si raw material, and the Al raw material described above are weighed out to have a desired target composition. The various weighed out raw materials are melted in a melting furnace and the produced molten metal is discharged into a mold to produce an ingot.

In order to prevent oxidation and nitriding of the metal in the molten metal state, it is preferable to utilize a vacuum melting furnace as the melting furnace. Furthermore, in order to prevent carbonization of Ni, it is preferable to utilize a ceramic crucible or the like without utilizing a carbonaceous member.

(Hot Rolling Step S02)

Subsequently, a rolled plate is produced by subjecting the ingot obtained in the melting and casting step S01 to hot rolling. The total rolling reduction in the hot rolling is preferably within a range of 50% or more and 80% or less. Due to this hot rolling step S02, a cast structure is destroyed and the recrystallization of the next heat treatment step and uniform dissolving of the additive elements as a solid solution are promoted.

Also, a temperature of the hot rolling is preferably within a range of 500° C. or more and 900° C. or less. In order to minimize rolling cracks, when the temperature drops to less than 500° C., it is preferable to perform heating to 500° C. or higher and 900° C. or less again and perform rolling.

(Heat Treatment Step S03)

Subsequently, the crystal grains are recrystallized by subjecting the rolled plate obtained in the hot rolling step S02 to heat treatment. Through the heat treatment step S03, the average crystal grain diameter is adjusted to 100 μm or less. In order to reduce an area ratio of a Ni phase having an average crystal grain diameter of 100 μm or less and a Ni content of 99.0 mass % or more to 13% or less, a heat treatment temperature is preferably within a range of 600° C. or more and 900° C. or less. Furthermore, a holding time at the heat treatment temperature is preferably within a range of 30 minutes or more and 90 minutes or less.

(Machining Step S04)

Subsequently, a nickel alloy sputtering target with a prescribed shape and prescribed dimensions is obtained by subjecting the rolled plate which has been subjected to the heat treatment step S03 to cutting processing, grinding processing, and the like.

The nickel alloy sputtering target which is the embodiment is thus produced as described above.

According to the nickel alloy sputtering target in the embodiment having the above constitution, since the average crystal grain diameter is 100 μm or less, it is possible to minimize the concentration of Si at the crystal grain boundaries, it is possible to minimize the occurrence of abnormal electric discharge, and it is possible to stably perform sputtering film formation. Furthermore, it is possible to minimize variation in the sputtering rate on the sputtered surface and form a nickel alloy film having a uniform film thickness.

Since the element capable of decreasing the Curie temperature of nickel is contained and the area ratio of the Ni phase having a Ni content of 99.0 mass % or more is 13% or less, even when the element capable of decreasing the Curie temperature is sufficiently dissolved in nickel as a solid solution, the magnetism is weakened, a magnetic flux leakage increases, and the magnetron sputtering device is utilized, it is possible to prevent the sputtering target from adsorbing to the device and it is possible to stably perform sputtering film formation. Furthermore, even when the sputtering progresses, the erosion portion is formed relatively wide and it is possible to improve the utilization efficiency of the sputtering target.

Also, when the area ratio of the high-purity Ni phase having a Ni content of 99.5 mass % or more is limited to 5% or less in the nickel alloy sputtering target which is the embodiment, even when the element capable of decreasing the Curie temperature is more sufficiently dissolved in nickel as a solid solution, the magnetism is weakened, the magnetic flux leakage increases, and the magnetron sputtering device is utilized, it is possible to prevent the sputtering target from adsorbing to the device and it is possible to stably perform sputtering film formation. Furthermore, even when the sputtering progresses, the erosion portion is formed relatively wide and it is possible to improve the utilization efficiency of the sputtering target.

Furthermore, one or both of Si and Al are contained as the element capable of decreasing the Curie temperature and the total content of Si and Al is 3 mass % or more in the nickel alloy sputtering target which is the embodiment, even when sufficient amounts of Si atoms and Al atoms which are dissolved in nickel as a solid solution are secured, the magnetism is weakened, a magnetic flux leakage increases, and the magnetron sputtering device is utilized, it is possible to prevent the sputtering target from adsorbing to the device and it is possible to stably perform sputtering film formation. In addition, even when the sputtering progresses, the erosion portion is formed relatively wide and it is possible to improve the utilization efficiency of the sputtering target.

Moreover, when the total content of Si and Al is 10 mass % or less, it is possible to sufficiently minimize the formation of compounds containing Si and Al, it is possible to minimize the occurrence of abnormal electric discharge at the time of sputtering, and it is possible to more stably perform sputtering film formation.

Although the embodiments of the present invention have been described above, the present invention is not limited thereto and can be appropriately changed without departing from the technical idea of the present invention.

### EXAMPLES

The results of an evaluation test in which the nickel alloy sputtering targets of the present invention described above are evaluated will be described below.

Nickel alloy sputtering targets in examples of the present invention and a comparative examples were produced in accordance with the production method described in the embodiment.

First, a Ni raw material (a Ni plate) having a purity of 99.9 mass % or more, a Si raw material (Si grains) having a purity of 99.9 mass % or more, and an Al raw material (Al grains) having a purity of 99.9 mass % or more were prepared.

These raw materials were weighed to have the compositions shown in Table 1. Ingots (width of 155 mm×thickness of 40 mm×length of 220 mm) were obtained by heating various weighed raw materials to 1500° C. or higher using a vacuum melting furnace to melt the various weighed raw materials and discharging the obtained molten metal into a mold. Nickel alloy sputtering targets (150 mm×500 mm×thickness of 5 mm) in examples of the present invention and comparative examples having a rectangular flat plate shape were produced by performing hot rolling and heat treatment under the conditions shown in Table 1.

With regard to each of the nickel alloy sputtering targets obtained as described above, a component composition, a composition variation, an average crystal grain diameter, an area ratio of a Ni phase having a Ni content of 99.0 mass % or more, an area ratio of a high-purity Ni phase having a Ni content of 99.5 mass % or more, a magnetic flux leakage, and a specific resistance value were evaluated as follows. The evaluation results are shown in Table 2.

Also, the number of abnormal electric discharges and the film thickness variation of the obtained nickel film were evaluated by performing sputtering film formation as follows using the obtained nickel alloy sputtering targets. The evaluation results are shown in Table 2.

(Component Composition/Composition Variation)

As shown in FIG. 2, measurement samples were taken from five points such as an intersection (1) in which diagonal lines intersect of the sputtered surface of the obtained nickel alloy sputtering target and corner portions (2), (3), (4), and (5) on the diagonal lines and were subjected to pre-treatment with acid, and then were subjected to ICP analysis. The corner portions (2), (3), (4), and (5) were within the range of 10% or less of the total length of the diagonal lines directed inward from the corner portions. As a result of the measurement, it was confirmed that an average composition was substantially the same as a blending composition.

Also, differences between maximum values and minimum values of analysis values of Si and Al in five measurement sample are shown in Table 2 as “composition variation.”

(Average Crystal Grain Diameter)

As shown in FIG. 2, samples were taken from five points such as an intersection (1) in which diagonal lines intersect of the sputtered surface of the obtained nickel alloy sputtering target and corner portions (2), (3), (4), and (5) on the diagonal lines. After the surface of each of the taken samples (the surface corresponding to the sputtered surface) was subjected to polishing processing, the polished surface was etched with an etching solution.

Subsequently, the polished surface was microscopically observed using an optical microscope and the crystal grain diameter was measured through the cutting method defined in JIS H 0501:1986.

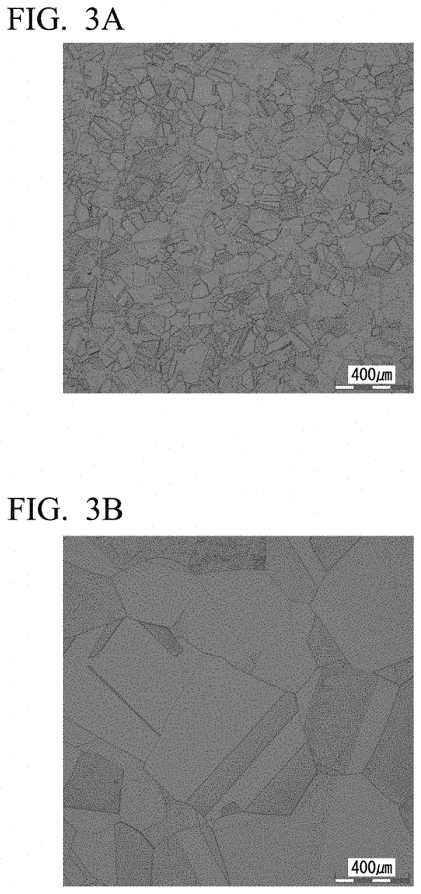

The crystal grain diameter was measured in each of the above five samples and the average crystal grain diameter was calculated. The evaluation results are shown in Table 2. Furthermore, the results of microstructure observation of Example 2 of the present invention and Comparative Example 4 are shown in FIGS. 3A and 3B, respectively.

(Area Ratio of Ni Phase/High-Purity Ni Phase)

As shown in FIG. 2, samples were taken from five points such as an intersection (1) in which diagonal lines intersect of the sputtered surface of the obtained nickel alloy sputtering target and corner portions (2), (3), (4), and (5) on the diagonal lines. After each of the taken samples is embedded in an epoxy resin and the surface (the surface corresponding to the sputtered surface) was subjected to polishing processing, Ni, Si, and Al were mapped with a 60-fold field of view (1400 gm×2000 μm) using FE-EPMA (DCA-8500F manufactured by JEOL Ltd.).

For each of the mapping results, semi-quantitative calculation was performed assuming that only Ni, Si, and Al were present for each pixel using a quantitative map function of software attached to the device and a quantitative map showing the content (mass %) of each pixel of Ni, Si, and Al was created.

Based on the prepared quantitative map, the area ratio of the Ni phase having a Ni content of 99.0 mass % or more in the field of view and the area ratio of the high-purity Ni phase having a Ni content of 99.5 mass % or more were calculated. The area ratio is the area ratio of the Ni phase obtained by counting the number of pixels having a Ni content of 99.0 mass % or more or 99.5 mass % or more, calculating a value of each measurement place by dividing the number of pixels by the total number of pixels in the field of view, and calculating an average value of the values in (1) to (5). The evaluation results are shown in Table 2.

(Magnetic Flux Leakage)

A magnetic flux measuring device having a structure in which a magnet (a horseshoe-shaped magnet: Alnico magnet 5K215 manufactured by Dexter) for generating magnetic flux was disposed below a table made of a non-magnetic material (for example, aluminum), a hole probe which can adjust a relative measurement position was disposed above the nickel alloy sputtering target disposed below the table, and a Gauss meter was connected to this hole probe was prepared.

An amount of magnetic flux A (KG) on an upper surface of the table when the nickel alloy sputtering target was not displaced on the table and an amount of magnetic flux B (KG) on an upper surface of the nickel alloy sputtering target when the nickel alloy sputtering target was placed on the table were measured using the magnetic flux measuring device. Leakage magnetic flux (%) was calculated through the following expression. The evaluation results are shown in Table 2:

Leakage Magnetic Flux (%)=B/A×100

(Specific Resistance Value)

The specific resistance of the nickel alloy sputtering target was measured using a four-probe method. As a measuring device, Loresta-GP of Mitsubishi Chemical Analytech Co., Ltd. was utilized. The evaluation results are shown in Table 2.

(Abnormal Electric Cischarge)

The nickel alloy sputtering target was soldered to a backing plate made of oxygen-free copper and this was installed on a magnetron type direct current (DC) sputter device.

Subsequently, film formation using a sputter method was performed continuously for 60 minutes under the following sputtering conditions. During this sputtering film formation, the number of occurrences of abnormal electric discharge was counted using an arc counter attached to a power supply of the DC sputter device. The evaluation results are shown in Table 2.
Arrival degree of vacuum: 5×10⁻⁵ Pa
Ar gas pressure: 0.3 Pa
Sputter output: DC 1000 W

(Film Thickness Variation)

The nickel alloy sputtering target was soldered to a backing plate made of oxygen-free copper and this was installed in a magnetron type DC sputter device. Furthermore, a 100 mm square glass substrate was installed in the magnetron type DC sputter device.

Subsequently, a nickel alloy film was formed on a surface of the glass substrate under the following sputtering conditions with a target thickness of 300 nm:
Target glass substrate distance: 60 mm
Arrival degree of vacuum: 5×10⁻⁵ Pa
Ar gas pressure: 0.3 Pa
Sputter output: DC 1000 W

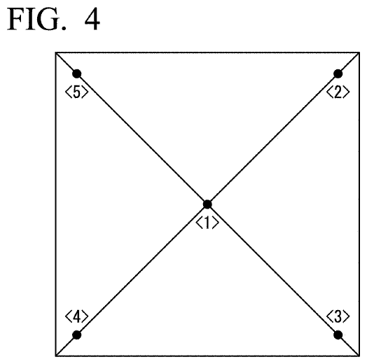

With regard to the nickel alloy film formed on the glass substrate, as shown in FIG. 4, film thicknesses were measured at five points such as an intersection <1> in which diagonal lines on a film-forming surface of the glass substrate intersect, corner portions <2>, <3>, <4>, and <5> on the diagonal lines using a step measuring device. The corner portions <2>, <3>, <4>, and <5> were set within the range of 10% or less of the total length of diagonal lines directed inward from the corner portions. An average value of the measured film thicknesses was obtained, a maximum value (a maximum film thickness) and a minimum value (a minimum film thickness) of the measured values of the film thicknesses were extracted and a difference between the maximum film thickness and the minimum film thickness was calculated. The evaluation results are shown in Table 2.

(Utilization Efficiency)

Continuous sputtering was performed under the following sputtering conditions and the utilization efficiency of the nickel alloy sputtering target was measured when the utilization was completed (until the thinnest portion of the target became 1.5 mm). The evaluation results are shown in Table 2.
Arrival degree of vacuum: 5×10⁻⁵ Pa
Ar gas pressure: 0.3 Pa
Sputter output: DC 1000 W

The utilization efficiency was calculated using the following expression:

Utilization efficiency (%)=(1−(target weight after utilization/target weight before utilization))×100

TABLE 1

| | | Blending composition | | | Hot rolling step | | Heat treatment step | |
|---|---|---|---|---|---|---|---|---|
| | | (mass %) | | | Hot rolling | Total treatment | Holding temperature | Holding time |
| | | Si | Al | Ni | temperature (° C.) | rate (%) | (° C.) | (h) |
| Example of | 1 | 3 | — | Residual | 800 | 80 | 800 | 1.0 |
| present | 2 | 5 | — | Residual | 800 | 80 | 800 | 1.0 |
| invention | 3 | 10 | — | Residual | 800 | 80 | 800 | 1.0 |
| | 4 | 5 | — | Residual | 900 | 80 | 900 | 1.0 |
| | 5 | 5 | — | Residual | 500 | 80 | 500 | 1.0 |
| | 6 | 5 | — | Residual | 800 | 80 | 800 | 0.5 |
| | 7 | 5 | — | Residual | 800 | 80 | 800 | 2.0 |
| | 8 | 5 | — | Residual | 800 | 50 | 800 | 1.0 |
| | 9 | 3 | — | Residual | 800 | 50 | 800 | 1.0 |
| | 11 | — | 3 | Residual | 800 | 80 | 800 | 1.0 |
| | 12 | — | 6 | Residual | 800 | 80 | 800 | 1.0 |
| | 13 | — | 10 | Residual | 800 | 80 | 800 | 1.0 |
| | 14 | — | 6 | Residual | 900 | 80 | 900 | 1.0 |
| | 15 | — | 6 | Residual | 500 | 80 | 500 | 1.0 |
| | 16 | — | 6 | Residual | 800 | 80 | 800 | 0.5 |
| | 17 | — | 6 | Residual | 800 | 80 | 800 | 2.0 |
| | 18 | — | 6 | Residual | 800 | 50 | 800 | 1.0 |
| | 19 | — | 3 | Residual | 800 | 50 | 800 | 1.0 |
| | 21 | 1.5 | 1.5 | Residual | 800 | 80 | 800 | 1.0 |
| | 22 | 3 | 3 | Residual | 800 | 80 | 800 | 1.0 |
| | 23 | 5 | 5 | Residual | 800 | 80 | 800 | 1.0 |
| | 24 | 12 | — | Residual | 800 | 80 | 800 | 1.0 |
| | 25 | — | 12 | Residual | 800 | 80 | 800 | 1.0 |
| Comparative | 1 | — | — | Residual | 800 | 80 | 800 | 1.0 |
| Example | 2 | 5 | — | Residual | 1000 | 80 | 1000 | 1.0 |
| | 3 | 5 | — | Residual | 450 | 80 | — | — |
| | 4 | 3 | — | Residual | 800 | 20 | 800 | 1.0 |
| | 5 | — | 6 | Residual | 1000 | 80 | 1000 | 1.0 |
| | 6 | — | 6 | Residual | 450 | 80 | — | — |
| | 7 | — | 3 | Residual | 800 | 20 | 800 | 1.0 |

TABLE 2

| | | | | | | | | Number of | | |
|---|---|---|---|---|---|---|---|---|---|---|
| | | | | | | | | occurrences | | |
| | | | | Area | | | | of | | |
| | | | | ratio | Area ratio | | Specific | abnormal | Film | |
| | | Composition | Average crystal | of Ni | of high- | Leakage | resistance | electric | thickness | Utilization |
| | | variation | grain | phase | purity Ni | magnetic | (×10⁶ | discharges | difference | efficiency |
| | | (mass %) | diameter(μm) | (%) | phase (%) | flux (%) | Ωcm) | (times) | (nm) | (%) |
| Example of | 1 | 0.2 | 79 | 9.5 | 2.1 | 57 | 32 | 4 | 35 | 21 |
| present | 2 | 0.3 | 80 | 6.3 | 2.3 | 100 | 38 | 2 | 12 | 32 |
| invention | 3 | 0.3 | 75 | 2.1 | 0.7 | 100 | 60 | 1 | 15 | 30 |
| | 4 | 0.2 | 95 | 5.9 | 1.7 | 100 | 37 | 2 | 18 | 31 |
| | 5 | 0.3 | 62 | 7.0 | 3.2 | 100 | 38 | 0 | 15 | 30 |
| | 6 | 0.1 | 58 | 7.2 | 2.3 | 92 | 38 | 3 | 31 | 27 |
| | 7 | 0.2 | 86 | 5.9 | 1.9 | 100 | 39 | 1 | 16 | 31 |
| | 8 | 0.4 | 84 | 6.4 | 2.1 | 100 | 38 | 1 | 17 | 31 |
| | 9 | 0.3 | 88 | 12.8 | 6.1 | 48 | 30 | 2 | 20 | 19 |
| | 11 | 0.2 | 21 | 9.6 | 2.2 | 48 | 22 | 5 | 37 | 21 |
| | 12 | 0.1 | 34 | 6.2 | 2.3 | 100 | 45 | 1 | 13 | 30 |
| | 13 | 0.3 | 45 | 2.4 | 0.6 | 100 | 66 | 2 | 14 | 32 |
| | 14 | 0.2 | 40 | 5.8 | 1.5 | 100 | 43 | 0 | 22 | 31 |
| | 15 | 0.3 | 31 | 7.2 | 3.1 | 100 | 42 | 1 | 16 | 29 |
| | 16 | 0.3 | 35 | 7.1 | 2.1 | 87 | 40 | 2 | 34 | 26 |
| | 17 | 0.1 | 41 | 6.1 | 2.2 | 100 | 42 | 1 | 18 | 30 |
| | 18 | 0.4 | 35 | 6.7 | 1.8 | 100 | 44 | 1 | 21 | 30 |
| | 19 | 0.2 | 31 | 12.4 | 5.5 | 45 | 21 | 1 | 20 | 19 |
| | 21 | 0.2 | 66 | 9.6 | 3.1 | 67 | 35 | 5 | 36 | 24 |
| | 22 | 0.1 | 72 | 6.2 | 2.7 | 100 | 47 | 2 | 18 | 30 |
| | 23 | 0.3 | 78 | 2.4 | 0.8 | 100 | 64 | 1 | 22 | 31 |
| | 24 | 0.3 | 56 | 1.7 | 0.4 | 100 | 93 | 26 | 32 | 31 |
| | 25 | 0.3 | 43 | 1.6 | 0.3 | 100 | 76 | 22 | 31 | 31 |
| Comparative | 1 | — | 75 | 100 | 100 | 22 | 8 | 2 | 41 | 15 |
| Example | 2 | 0.3 | 364 | 8.5 | 3.2 | 100 | 40 | 10 | 51 | 31 |
| | 3 | — | — | — | — | — | — | — | — | — |
| | 4 | 0.6 | 99 | 16.3 | 4.5 | 25 | 38 | 5 | 45 | 16 |
| | 5 | 0.3 | 157 | 8.9 | 3.4 | 100 | 38 | 16 | 48 | 30 |
| | 6 | — | — | — | — | — | — | — | — | — |
| | 7 | 0.7 | 75 | 15.8 | 4.8 | 25 | 43 | 2 | 47 | 16 |

In Comparative Example 1 in which an element capable of decreasing the Curie temperature of nickel is not contained, an area ratio of the Ni phase and the high-purity Ni phase was 100%. Furthermore, the leakage magnetic flux was as low as 22% and the magnetism could not be weakened. In addition, the film thickness difference increased and the uniformity of the film decreased. Moreover, the utilization efficiency of the sputtering target was as low as 15%.

In Comparative Example 2 and Comparative Example 5 in which the hot rolling temperature of the hot rolling step and the heat treatment temperature of the heat treatment step were 1000° C. and the average crystal grain diameter was coarsened to exceed 100 μm. Particularly, in Comparative Example 2, the average crystal grain diameter was significantly coarsened to 364 μm. For this reason, the number of abnormal electric discharges at the time of sputtering film formation increased. Furthermore, the difference in film thickness increased and the uniformity of the film decreased.

In Comparative Example 3 and Comparative Example 6 in which the hot rolling temperature in the hot rolling step was 450° C., cracks occurred at the time of hot rolling. For this reason, the steps and the evaluation after hot treatment were stopped. In

Comparative Example 4 and Comparative Example 7 in which the total treatment ratio of the hot rolling steps was 20%, the area ratio of the Ni phase exceeded 13% and the leakage magnetic flux was 25%. Furthermore, the difference in film thickness increased and the uniformity of the film decreased. In addition, the utilization efficiency of the sputtering target was as low as 16%.

On the other hand, in Examples 1 to 25 of the present invention in which Si and Al which were elements capable of decreasing the Curie temperature of nickel were contained, the area ratio of the Ni phase having a Ni content of 99.0 mass % or more was 13% or less, and the average crystal grain diameter was 100 μm or less, the number of abnormal electric discharges decreased and the film thickness difference was kept small. Furthermore, the utilization efficiency of the sputtering target was 19% or more.

As described above, according to the examples of the present invention, the magnetism was weakened, the magnetic flux leakage increased, and the coarsening of the crystal grains was minimized so that a nickel alloy thin film with a uniform film thickness could be stably formed. Furthermore, it was confirmed that a wide erosion portion is formed when the sputtering progresses and it is possible to provide a nickel alloy sputtering target capable of improving the utilization efficiency.

### INDUSTRIAL APPLICABILITY

According to the present invention, the magnetism is weakened, the magnetic flux leakage increases, the coarsening of the crystal grains is minimized, and a nickel alloy thin film with a uniform film thickness can be stably formed. Furthermore, it is possible to provide a nickel alloy sputtering target in which utilization efficiency can be improved by forming a wide erosion portion when sputtering progresses. Therefore, the present invention can be used industrially.

What is claimed is:

1. A nickel alloy sputtering target, comprising:
a nickel alloy containing an element capable of decreasing the Curie temperature of nickel,
wherein an area ratio of a Ni phase having a Ni content of 99.0 mass % or more is 13% or less and
an average crystal grain diameter is 100 μm or less.

2. The nickel alloy sputtering target according to claim 1, wherein an area ratio of a high-purity Ni phase having a Ni content of 99.5 mass % or more is 5% or less.

3. The nickel alloy sputtering target according to claim 1, wherein, as the element capable of decreasing the Curie temperature of nickel, one or both of Si and Al are used and a total content of Si and Al is within a range of 3 mass % or more and 10 mass % or less.

4. The nickel alloy sputtering target according to claim 2, wherein, as the element capable of decreasing the Curie temperature of nickel, one or both of Si and Al are contained and a total content of Si and Al is within the range of 3 mass % or more and 10 mass % or less.
